(19) United States
(12) Patent Application Publication
(10) Pub. No.: US 2026/0128199 A1
(43) Pub. Date: May 7, 2026

(54) SUPERCONDUCTING MAGNET AND MAGNETIC RESONANCE IMAGING APPARATUS

(71) Applicant: CANON MEDICAL SYSTEMS CORPORATION, Otawara-shi (JP)

(72) Inventors: Takehiro SHIBUYA, Nasushiobara Tochigi (JP); Hiromi KAWAMOTO, Yaita Tochigi (JP); Katsutoshi MIZUNO, Nasushiobara Tochigi (JP); Sadanori TOMIHA, Nasushiobara Tochigi (JP); Michiru KAJIWARA, Nasushiobara Tochigi (JP)

(73) Assignee: CANON MEDICAL SYSTEMS CORPORATION, Otawara-shi (JP)

(21) Appl. No.: 19/378,438

(22) Filed: Nov. 4, 2025

(30) Foreign Application Priority Data
Nov. 6, 2024 (JP) 2024-194321

(51) Int. Cl. H01F 6/04; G01R 33/34; H01F 6/06

(52) U.S. Cl. CPC H01F 6/04; G01R 33/34023; H01F 6/06

(57) ABSTRACT

A superconducting magnet apparatus includes a superconducting coil, a structure, a refrigerant tank, a heat exchanger, a freezer, a solid heat conductor, and a vacuum container. The superconducting coil is formed of a superconducting wire that forms a magnetic field. The structure is formed of a superconductor and is electrically connected to the superconducting coil. The refrigerant tank stores a refrigerant. The heat exchanger is exposed to inside of the refrigerant tank. The freezer cools the refrigerant. The solid heat conductor makes direct or indirect thermal connection between the refrigerant tank and the superconducting coil and the structure. The superconducting coil or the structure is formed using at least two structures having different operation temperatures or superconducting characteristics for superconduction.

### CROSS-REFERENCE TO RELATED APPLICATIONS

This application is based upon and claims the benefit of priority from Japanese Patent Application No. 2024-194321, filed on Nov. 6, 2024; the entire contents of which are incorporated herein by reference.

### FIELD

Embodiments described herein and the drawings relate generally to a superconducting magnet apparatus and a magnetic resonance imaging apparatus.

### BACKGROUND

A magnetic resonance imaging (MRI) apparatus including a superconducting magnet apparatus as a static magnetic field magnet that generates a static magnetic field in an imaging space in which a subject is arranged has been known.

In general, a superconducting magnet apparatus included in an MRI apparatus includes a cooling container that is filled with a refrigerant, such as liquid helium, a freezer that cools the refrigerant in the cooling container, and a superconducting coil that is immersed in the refrigerant in the cooling container. The superconducting coil is formed of a superconducting wire and is cooled by the refrigerant and transmits electricity in a state of having shifted to a superconducting state, thereby generating a magnetic field.

In recent years, such superconducting magnet apparatuses have been required to efficiently cool a plurality of structures to be cooled while reducing the amount of a refrigerant.

### BRIEF DESCRIPTION OF THE DRAWINGS

FIG. 1 is a diagram illustrating an example of a configuration of an MRI apparatus according to a first embodiment;

FIG. 2 is a diagram illustrating an example of a superconducting magnet apparatus according to a comparative example of the first embodiment;

FIG. 3 is a diagram illustrating an example of the superconducting magnet apparatus according to the first embodiment;

FIG. 4 is a diagram illustrating a modification of the superconducting magnet apparatus according to the first embodiment;

FIG. 5 is a diagram illustrating an example of a superconducting magnet apparatus according to a second embodiment;

FIG. 6 is a diagram illustrating an example of a superconducting magnet apparatus according to a third embodiment;

FIG. 7 is a diagram illustrating an example of a superconducting magnet apparatus according to a fourth embodiment;

FIG. 8 is a diagram illustrating an example of a superconducting magnet apparatus according to a fifth embodiment;

FIG. 9 is a diagram illustrating an example of a superconducting magnet apparatus according to a sixth embodiment;

FIG. 10 is a diagram illustrating an example of a superconducting magnet apparatus according to a seventh embodiment;

FIG. 11 is a diagram illustrating an example of a superconducting magnet apparatus according to an eighth embodiment.

### DETAILED DESCRIPTION

A superconducting magnet apparatus according to an embodiment includes a superconducting coil, a structure, a refrigerant tank, a heat exchanger, a freezer, a solid heat conductor, and a vacuum container. The superconducting coil is formed of a superconducting wire that forms a magnetic field. The structure is formed of a superconductor and is electrically connected to the superconducting coil. The refrigerant tank stores a refrigerant. The heat exchanger is exposed to the inside of the refrigerant tank. The freezer cools the refrigerant. The solid heat conductor makes direct or indirect thermal connection between the refrigerant tank and the superconducting coil and the structure. The vacuum container seals in the superconducting coil, the structure, the refrigerant tank, the heat exchanger, the freezer, and the solid heat conductor. The superconducting coil or the structure is formed using at least two structures having different operation temperatures or superconducting characteristics for superconduction.

With reference to the accompanying drawings, embodiments of a superconducting magnet apparatus and an MRI apparatus according to the present application will be described in detail below.

### First Embodiment

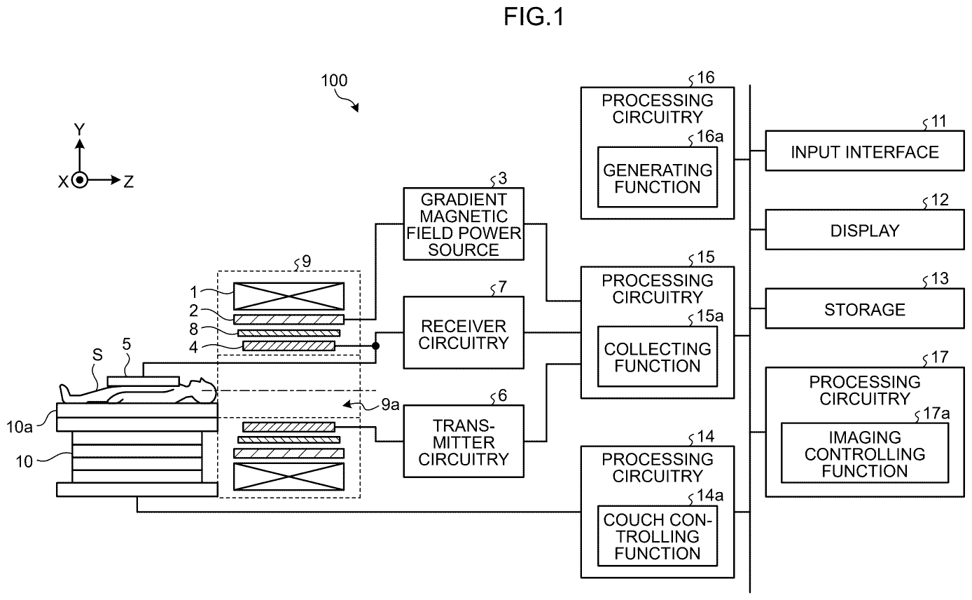

FIG. 1 is a diagram illustrating an example of a configuration of an MRI apparatus according to a first embodiment.

For example, as illustrated in FIG. 1, an MRI apparatus 100 includes a static magnetic field magnet 1, a gradient coil 2, a gradient magnetic field power source 3, a whole body radio frequency (RF) coil 4, a local RF coil 5, a transmitter circuitry 6, a receiver circuitry 7, a RF shield 8, a gantry 9, a couch 10, an input interface 11, a display 12, a storage 13, and processing circuitries 14 to 17.

The static magnetic field magnet 1 generates a static magnetic field in an imaging space in which a subject S is arranged. Specifically, the static magnetic field magnet 1 is formed into a hollow and approximately cylindrical shape (including one having a cross section that is orthogonal to a center axis and of which shape is elliptic) and generates a static magnetic field in the imaging space that is formed on an inner circumferential side of the static magnetic field magnet 1.

The gradient coil 2 is arranged on an inner side of the static magnetic field magnet 1 and generates a gradient magnetic field in the imaging space in which the subject S is arranged. Specifically, the gradient coil 2 is formed into a hollow and approximately cylindrical shape (including one having a cross section that is orthogonal to a center axis and of which shape is elliptic) and includes a X-coil, a Y-coil, and a Z-coil corresponding respectively to an X-axis, a Y-axis, and a Z-axis that are orthogonal to one another. Based on currents supplied from the gradient magnetic field power source 3, the X-coil, the Y-coil, and the Z-coil generate gradient magnetic fields that vary linearly along the respective axes in the imaging space. The Z-axis is set along a magnetic flux of the static magnetic field that is generated by the static magnetic field magnet 1. The X-axis is set along a horizontal direction orthogonal to the Z-axis and the Y-axis is set along a vertical direction orthogonal to the Z-axis. The X-axis, the Y-axis, and the Z-axis form an apparatus coordinate system unique to the MRI apparatus 100.

The gradient magnetic field power source 3 supplies currents to the gradient coil 2, thereby generating gradient magnetic fields in the imaging space. Specifically, the gradient magnetic field power source 3 supplies currents individually to the X-coil, the Y-coil, and the Z-coil of the gradient coil 2, thereby generating gradient magnetic fields that vary linearly respectively along a readout direction, a phase encode direction, and a slice direction that are orthogonal to one another in the imaging space. An axis along the readout direction, an axis along the phase encode direction, and an axis along the slice direction form a logical coordinate system for defining a slice area or a volume area to be imaged.

The gradient magnetic fields along the readout direction, the phase encode direction, and the slice direction, respectively, are superimposed onto the static magnetic field that is generated by the static magnetic field magnet 1, thereby imparting spatial positional information to a nuclear magnetic resonance (NMR) signal that is generated from the subject S. Specifically, the gradient magnetic field in the readout direction changes a frequency of the NMR signal according to a position in the readout direction, thereby imparting readout-direction positional information to the NMR signal. The gradient magnetic field in the phase encode direction changes a phase of the NMR signal according to a position in the phase encode direction, thereby imparting phase-encode-direction positional information to the NMR signal. The gradient magnetic field in the slice direction changes a phase of the NMR signal according to a position in the slice direction each time a three-dimensional MR image (volume image) is captured, thereby imparting slice-direction positional information to the NMR signal.

The whole body RF coil 4 is arranged on an inner circumferential side of the gradient coil 2, applies an RF pulse (such as an excitation pulse) to the subject S that is arranged in the imaging space, and receives an NMR signal (such as an echo signal) that is generated from the subject S due to an effect of the RF pulse. Specifically, the whole body RF coil 4 is formed into a hollow and approximately cylindrical shape (including one having a cross section that is orthogonal to a center axis and of which shape is elliptic) and, based on a RF pulse signal that is supplied from the transmitter circuitry 6, applies an RF pulse to the subject S that is arranged in the imaging space positioned on the inner circumferential side. The whole body RF coil 4 receives an NMR signal that is generated from the subject S due to an effect of the RF pulse and outputs the received NMR signal to the receiver circuitry 7. For example, the whole body RF coil 4 is a bird cage coil or a transverse electromagnetic (TEM) coil.

The local RF coil 5 is arranged near the subject S in imaging and receives the NMR signal that is generated from the subject S. Specifically, the local RF coil 5 is prepared for each part of the subject S and is arranged near a part of which image is to be captured when an image of the subject S is captured, receives the NMR signal that is generated from the subject S due to an effect of the RF pulse that is applied by the whole body RF coil 4, and outputs the received NMR signal to the receiver circuitry 7. For example, the local RF coil 5 is a surface coil or a phased array coil configured by combining a plurality of surface coils as a coil element. Note that the local RF coil 5 may include a transmitting function of applying an RF pulse to the subject.

The transmitter circuitry 6 outputs an RF pulse signal corresponding to a resonance frequency (Larmor frequency) unique to subject nuclei placed in the static magnetic field to the whole body RF coil 4 or the local RF coil 5. Specifically, the transmitter circuitry 6 includes a pulse generator, an RF generator, a modulator, and an amplifier. The pulse generator generates a waveform of the RF pulse signal. The RF generator generates a RF signal of the resonance frequency. The modulator modulates an amplitude of the RF signal generated by the RF generator using the waveform generated by the pulse generator, thereby generating an RF pulse signal. The amplifier amplifies the RF pulses signal that is generated by the modulator and outputs the amplified RF pulse signal to the whole body RF coil 4 or the local RF coil 5.

The receiver circuitry 7 generates NMR data based on the NMR signal that is output from the whole body RF coil 4 or the local RF coil 5 and outputs the generated NMR data to the processing circuitry 15. Specifically, the receiver circuitry 7 includes a selector, a former amplifier, a phase detector, and an A/D (Analog/Digital) converter. The selector selectively inputs the NMR signal that is output from the whole body RF coil 4 or the local RF coil 5. The former amplifier amplifies the NRM signal that is output from the selector. The phase detector detects a phase of the NMR signal that is output from the amplifier. The A/D converter converts an analog signal that is output from the phase detector into a digital signal, thus generates NMR data, and outputs the generated NMR data to the processing circuitry 15. Note that all the sets of processing described as ones that the receiver circuitry 7 performs are not necessarily performed by the receiver circuitry 7, and the whole body RF coil 4 or the local RF coil 5 may perform part of the sets of processing (for example, the processing by the A/D converter).

The RF shield 8 is arranged between the gradient coil 2 and the whole body RF coil 4 and shields the gradient coil 2 from the RF pulse that is generated by the whole body RF coil 4. Specifically, the RF shield 8 is formed into a hollow and approximately cylindrical shape (including one having a cross section that is orthogonal to a center axis of the cylinder and of which shape is elliptic) and is arranged in a space on an inner circumferential side of the gradient coil 2 such that the RF shield 8 covers an outer circumferential surface of the whole body RF coil 4.

The gantry 9 has a bore 9a that is hollow and that is formed into an approximately cylindrical shape (including one having a cross section that is orthogonal to a center axis and of which shape is elliptic) and stores the static magnetic field magnet 1, the gradient coil 2, the whole body RF coil 4, and the RF shield 8. Specifically, the gantry 9 stores them with the whole body RF coil 4 being arranged on an outer circumferential side of the bore 9a, the RF shield 8 being arranged on an outer circumferential side of the whole body RF coil 4, the gradient coil 2 being arranged on an outer circumferential side of the RF shield 8, and the static magnetic field magnet 1 being arranged on an outer circumferential side of the gradient coil 2. The space in the bore 9a that the gantry 9 includes serves as an imaging space in which the subject S is arranged in imaging.

The couch 10 includes a couchtop 10a on which the subject S is placed and moves the couchtop 10a with the subject S being placed thereon into the imaging space when an image of the subject S is captured. For example, the couch 10 is set such that a longitudinal direction of the couchtop 10a is parallel to a center axis of the static magnetic field magnet 1.

The input interface 11 receives operations of inputting various types of instructions and various types of information from an operator. Specifically, the input interface 11 is connected to the processing circuitry 17, converts an input operation received from the operator into an electric signal, and outputs the electric signal to the processing circuitry 17. For example, the input interface 11 is realized using a trackball, a switch button, a mouse, a keyboard, a touch pad that performs an input operation by being touched on an operation surface, a touch screen obtained by integrating a display screen and a touch pad, non-contact input circuitry using an optical sensor, audio input circuitry, etc. The input interface 11 is not limited to only ones including physical operational parts, such as a mouse and a keyboard. For example, examples of the input interface 11 include electric signal processing circuitry that receives an electric signal corresponding to an input operation from an external input device that is arranged independently of the apparatus and outputs the electric signal to control circuitry.

The display 12 displays various types of information. Specifically, the display 12 is connected to the processing circuitry 17, converts data on various types of information transmitted from the processing circuitry 17 into electric signals for display, and outputs the electric signals. For example, the display 12 is realized using a liquid crystal monitor, a cathode ray tube (CRT) monitor, a touch panel, or the like.

The storage 13 stores various types of data. Specifically, the storage 13 is connected to the processing circuitries 14 to 17 and stores various types of data that are input and output by each of the processing circuitries. For example, the storage 13 is realized using a semiconductor memory device, such as a random access memory (RAM) or a flash memory, a hard disk, an optical disk, or the like.

The processing circuitry 14 includes a couch controlling function 14a. The couch controlling function 14a outputs electric signals for control to the couch 10, thereby controlling operations of the couch 10. For example, the couch controlling function 14a receives an instruction to move the couchtop 10a in the longitudinal direction, an up-down direction, or a left-right direction from the operator via the input interface 11 and causes a moving mechanism of the couchtop 10a that the couch 10 includes to move the couchtop 10a according to the received instruction.

The processing circuitry 15 includes a collecting function 15a. The collecting function 15a executes various types of pulse sequences, thereby collecting NMR data on the subject S. Specifically, the collecting function 15a drives the gradient magnetic field power source 3, the transmitter circuitry 6, and the receiver circuitry 7 according to sequence execution data that is output from the processing circuitry 17, thereby executing various types of pulse sequences. The sequence execution data is data is data representing a pulse sequence and is information defining timing at which the gradient magnetic field power source 3 supplies a current to the gradient coil 2 and an intensity of the supplied current, timing at which the transmitter circuitry 6 supplies a RF pulse signal to the whole body RF coil 4 and an intensity of the supplied RF pulse signal, timing at which the receiver circuitry 7 samples the NMR signal, etc. The collecting function 15a receives the NMR data that is output from the receiver circuitry 7 as a result of executing the pulse sequence and causes the storage 13 to store the NMR data. Positional information along each of the readout direction, the phase encode direction, and the slice direction is imparted to the NMR data that is stored in the storage 13 and thus the NMR data is stores as k-space data representing a two-dimensional or three-dimensional k-space.

The processing circuitry 16 includes a generating function 16a. The generating function 16a generates an MR image from the NMR data that is collected by the collecting function 15a of the processing circuitry 15. Specifically, under the control of the processing circuitry 17, the generating function 16a reads the NMR data that is collected by the collecting function 15a of the processing circuitry 15 from the storage 13 and performs reconstruction processing, such as Fourier transformation, on the read NMR data, thereby generating a two-dimensional or three-dimensional MR image. The generating function 16a causes the storage 13 to store the generated MR image.

The processing circuitry 17 includes an imaging controlling function 17a. The imaging controlling function 17a controls each of the components of the MRI apparatus 100, thereby performing entire control on the MRI apparatus 100. Specifically, the imaging controlling function 17a displays a graphical user interface (GUI) for receiving an operation of inputting various types of instructions and various types of information from the operator on the display 12 and controls each of the components of the MRI apparatus 100 according to an input operation that is received via the input interface 11. For example, the imaging controlling function 17a receives an input of an imaging condition from the operator and, based on the input imaging condition, sets a pulse sequence for collecting NMR data on the subject S. The imaging controlling function 17a generates sequence execution data representing the pulse sequence that is set and outputs the sequence execution data to the processing circuitry 15, thereby causing the collecting function 15a of the processing circuitry 15 to execute various types of pulse sequences. For example, the imaging controlling function 17a controls the generating function 16a of the processing circuitry 16, thereby reconstructing an MR image from the k-space data that is collected by the processing circuitry 15. For example, the imaging controlling function 17a reads the MR image that is stored in the storage 13 according to a request from the operator and causes the display 12 to display the read MR image.

Each of the processing circuitries 14 to 17 described above, for example, are realized using a processor. In this case, the processing functions that the respective processing circuitries include, for example, are stored in the storage 13 in a mode of programs executable by a computer. The respective processing circuitries read the respective programs from the storage 13 and execute the programs, thereby implementing the processing functions corresponding to the respective programs. In other words, in a state of having read the respective programs, the respective processing circuitries include the respective processing functions illustrated in FIG. 1.

Note that each of the processing circuitries 14 to 17 are realized by the single processor herein; however, embodiments are not limited to this. For example, the respective processing circuitries may be configured by combining a plurality of independent processors and the respective processors may execute the programs and thus implement the respective processing functions. The processing functions that the respective processing circuitries include may be appropriately distributed to or integrated into a single or a plurality of the processing circuitries and implemented. In the above-described description, the single storage 13 stores the programs corresponding to the respective processing functions; however, embodiments are not limited to this. For example, a configuration in which the storage circuitries are distributed according to each processing circuitry and are arranged and the respective processing circuitries read corresponding programs from the individual storage circuitries may be employed.

The example of the configuration of the MRI apparatus 100 according to the first embodiment has been described.

Under such a configuration, the MRI apparatus 100 according to the first embodiment includes a superconductive magnet device as the static magnetic field magnet 1 that generates a static magnetic field in the imaging space in which the subject S is arranged.

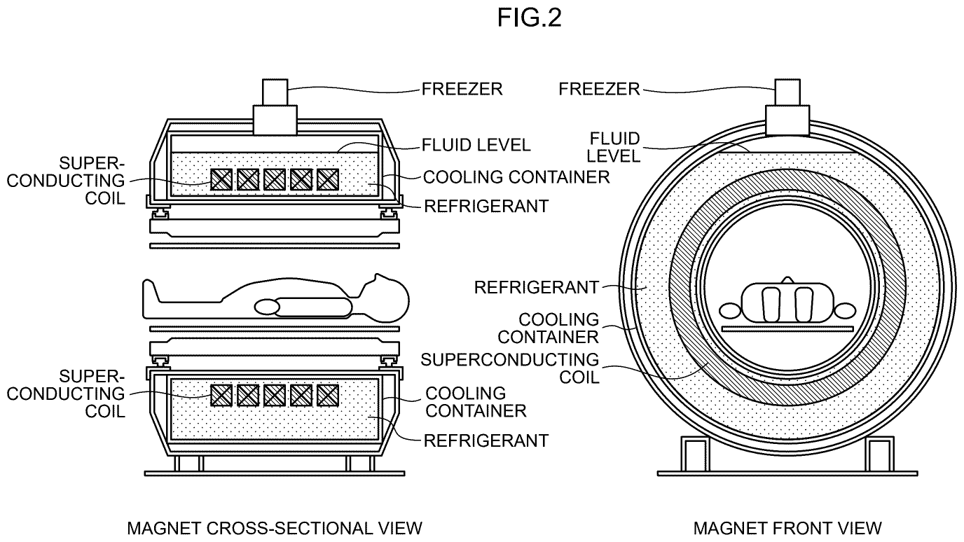

FIG. 2 is a diagram illustrating an example of the superconductive magnet device according to a comparative example of the first embodiment.

For example, as illustrated in FIG. 2, in general, the superconductive magnet device included in the MRI apparatus includes a cooling container that is filled with a refrigerant, such as liquid helium, a freezer that cools the refrigerant in the cooling container, and a superconducting coil that is immersed in the refrigerant in the cooling container. The superconducting coil is formed of a superconducting wire and is cooled by the refrigerant and transmits electricity in a state of having shifted to a superconducting state, thereby generating a magnetic field.

In recent years, such superconducting magnet apparatuses have been required to efficiently cool a plurality of structures to be cooled while reducing the amount of a refrigerant.

Thus, in the MRI apparatus 100 according to the first embodiment, the superconducting magnet apparatus that is included as the static magnetic field magnet 1 is configured to efficiently cool a plurality of structures to be cooled while reducing the amount of the refrigerant. The superconducting magnet apparatus that is included as the static magnetic field magnet 1 in the MRI apparatus 100 according to the present embodiment will be described in detail below.

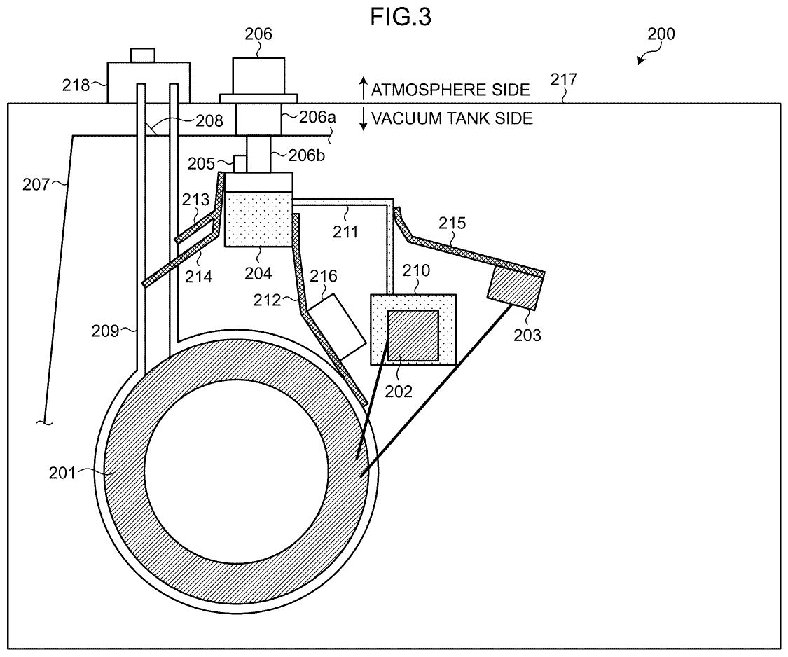

FIG. 3 is a diagram illustrating an example of a superconducting magnet apparatus 200 according to the first embodiment.

For example, as illustrated in FIG. 3, the superconducting magnet apparatus 200 according to the first embodiment includes a superconducting coil 201, a structure 202 and a structure 203, a refrigerant tank 204, a heat exchanger 205, a freezer 206, a radiation shield 207, a thermal anchor 208, a pre cooling pipe 209, a refrigerant tank 210, a pipe 211, solid heat conductors 212 to 215, a heat capacity ensuring member 216, a vacuum container 217, and a cover 218.

The superconducting coil 201 is formed of a superconducting wire that forms a magnetic field. Specifically, the superconducting coil 201 is formed of a wire of a low temperature superconductor (LTS) material.

Each of the structure 202 and the structure 203 is formed of a superconductor and is electrically connected to the superconducting coil 201. For example, the structure 202 is a persistent current switch (PCS), or the like. A PCS is a switch that is made by winding the superconducting wire by non-inductive winding and, is capable of turning off a circuit of a superconducting coil when shifted into a normal conduction state. For example, the structure 203 is a superconducting solder, or the like. The superconducting solder is solder that is used to couple a superconducting wire and enters into a superconducting state by being cooled.

The superconducting coil 201, the structure 202, and the structure 203 have different operation temperatures or superconducting characteristics for superconduction, respectively. The operation temperature is a temperature lower than a critical temperature and is a temperature that is set as a temperature enabling an operation in a superconducting state. The superconducting characteristic is a critical temperature (Tc), a critical magnetic field (Bc), or a critical current (Ic). The critical temperature (Tc) is a value of a temperature of shift from the superconducting state to a normal conduction state, the critical magnetic field (Bc) is a value of a magnetic field of shift from the superconducting state to the normal conduction state, and the critical current (Ic) is a value of a current of shift from the superconducting state to the normal conduction state.

Each of the superconducting coil 201, the structure 202, and the structure 203 is configured using a low temperature superconductor (LTS) material, a high temperature superconductor (HTS) material, a protective material, a matrix, a base material, and the like, that have different properties of thermal conductivity or specific heat. A LTS material is metal, such as NbTi or Nb₃Sn. An HTS material is, for example, metal, such as REBCO, MgB₂, or Bi. A protective material, a matrix, and a base material are, for example, metal, such as Cu, CuNi, Al, or Ag.

In the first embodiment, as for the superconducting coil 201, the structure 202, and the structure 203, the structure 202 has a heat capacity smaller than that of the superconducting coil 201 and the structure 203 has a heat capacity smaller than that of the structure 202.

The refrigerant tank 204 stores a refrigerant, such as liquid helium.

The heat exchanger 205 is exposed to the inside of the refrigerant tank 204, liquefies the vaporized refrigerant again, and returns the liquefied refrigerant to the refrigerant tank 204.

The freezer 206 cools the refrigerant in the refrigerant tank 204. Specifically, the freezer 206 has a high-temperature end 206a at a first temperature (for example, 50K) and a low-temperature end 206b at a second temperature (for example, 4K) lower than the first temperature and cools the refrigerant in the refrigerant tank 204 to the second temperature using the low-temperature end 206b.

The radiation shield 207 is arranged between the vacuum container 217 and the structures to be cooled that are housed in the vacuum container 217 and reduces thermal invasion to each of the structures. Specifically, the radiation shield 207 is formed of metal, such as aluminum or copper, is thermally connected to the high-temperature end 206a of the freezer 206, and is kept at the first temperature, thereby reducing thermal invasion from the vacuum container 217 at the temperature of atmosphere to each of the structures. Note that FIG. 3 illustrates only part of the radiation shield 207.

The thermal anchor 208 make thermal connection between the radiation shield 207 and the pre cooling pipe 209, thereby reducing thermal approach via the pre cooling pipe 209.

The pre cooling pipe 209 is arranged such that the pre cooling pipe 209 thermally makes contact with an outer circumferential part of the superconducting coil 201 and cools the superconducting coil 201 previously in a way that a cooling gas is circulated via an inlet and an outlet that are exposed to the outside of the vacuum container 217.

Specifically, in the pre cooling pipe 209, an area from the inlet and the outlet to a part to which the thermal anchor 208 is connected is formed of metal (for example, phosphorus-deoxidized copper) having low heat conductivity and an area from the part to which thermal anchor 208 is connected to the part making contact with the outer circumferential part of the superconducting coil 201 and an area serving as the outer circumferential part of the superconducting coil 201 are formed of metal having high heat conductivity.

The refrigerant tank 210 stores the refrigerant that is conveyed from the refrigerant tank 204, seals in the structure 202 in a state of being immersed in the refrigerant, and cools the structure 202 to the second temperature.

The pipe 211 is arranged between the refrigerant tank 204 and the refrigerant tank 210 and conveys the refrigerant from the refrigerant tank 204 to the structure 202 in the refrigerant tank 210.

In the pipe 211, at least two of parameters of size, heat conductivity, and heat load are set according to an operation temperature or superconductivity characteristics of the structure 202.

The solid heat conductors 212 to 215 are formed of metal (for example, pure aluminum or copper) having high heat conductivity and make direct or indirect thermal connection between the refrigerant tank 204 and the superconducting coil 201 and between the refrigerant tank 204 and the structure 203.

For example, the solid heat conductors 212 to 215 are formed of metal that is formed into a plate shape, an angular shape, a tape shape, or a sheet shape and that has high heat conductivity or metal that is formed into a form of a cylindrical pipe and in which heat conductivity is set according to the structure that makes thermal contact. Metal that is formed into a tape shape is more preferable than other materials in that it is easy to obtain and in that it is easy to manufacture.

Specifically, one of the ends of the solid heat conductor 212 thermally makes contact with the refrigerant tank 204 and the other end thermally makes contact with one part of the outer circumferential part of the superconducting coil 201 and the solid heat conductor 212 transmits the temperature of the refrigerant in the refrigerant tank 204 to the superconducting coil 201, thereby cooling the superconducting coil 201 to the second temperature.

One of the ends of each of the solid heat conductors 213 and 214 thermally makes contact with the refrigerant tank 204 and the other end thermally makes contact with one part in the area from the part of the pre cooling pipe 209 to which the thermal anchor 208 is connected to the part making contact with the outer circumferential part of the superconducting coil 201 and the solid heat conductors 213 and 214 transmit the temperature of the refrigerant in the refrigerant tank 204 to the superconducting coil 201 via the pre cooling pipe 209, thereby cooling the superconducting coil 201 to the second temperature.

One of the ends of the solid heat conductor 215 thermally makes contact with one part of the pipe 211 and the other end makes contact with the structure 203 and the solid heat conductor 215 transmits the temperature of the refrigerant in the refrigerant tank 204 to the structure 203 via the pipe 211, thereby cooling the structure 203 to the second temperature.

In each of the solid heat conductors 212 to 214, at least two of parameters of size, heat conductivity, and heat load are set according to the operation temperature or superconducting characteristics of the superconducting coil 201. In the solid heat conductor 215, at least two of parameters of size, heat conductivity, and heat load are set according to the operation temperature and superconductivity of the structure 203.

The heat capacity ensuring member 216 is formed of metal (for example, SUS) having given heat capacity, is attached to the solid heat conductor 212, and ensures the heat capacity of the solid heat conductor 212.

In the heat capacity ensuring member 216, at least two of parameters of size, heat conductivity, and heat load are set according to the operation temperature or superconductivity characteristics of the superconducting coil 201 that is cooled by the solid heat conductor 212.

The vacuum container 217 seals in the superconducting coil 201, the structure 202, the structure 203, the refrigerant tank 204, the heat exchanger 205, the radiation shield 207, the thermal anchor 208, the pre cooling pipe 209, the refrigerant tank 210, the pipe 211, the solid heat conductors 212 to 215, and the heat capacity ensuring member 216 that are described above.

The cover 218 is attached to the vacuum container 217 such that the cover 218 covers the inlet and the outlet of the pre cooling pipe 209, thereby making the inside in a vacuum state and thus maintaining the pre cooling pipe 209 in a vacuum state.

According to the above-described configuration, compared to an immersing superconducting magnet apparatus in which a superconducting coil is immersed in a refrigerant in a cooling container, it is possible to cool the superconducting coil in the small-sized refrigerant tank and thus reduce the amount of the refrigerant. Cooling the structures to be cooled individually using the solid heat conductor and the pipe makes it possible to efficiently cool each of the structures having different operation temperatures and superconducting characteristics.

Thus, according to the first embodiment, it is possible to cool the structures to be cooled efficiently while reducing the amount of the refrigerant.

According to the above-described configuration, compared to the immersing superconducting magnet apparatus, it is possible to reduce the amount of the refrigerant and accordingly it is possible to reduce the weight of the superconducting magnet apparatus.

According to the above-described configuration, attaching the heat capacity ensuring member 216 to the solid heat conductor 212 makes it possible to, even when the freezer 206 stops due to an electricity failure, or the like, slow an increase in the temperature of the solid heat conductor 212 that is caused by heat entering from the air via the freezer 206. Accordingly, for example, even in the case where the freezer 206 stops and s quench (an evet that the superconducting coil partly returns from a superconducting state to a normal conduction state) occurs, or the like, it is possible to inhibit the temperature of the superconducting coil 201 from increasing util recovery of the freezer 206 and shorten the time until completion of cooling the superconducting coil 201 after the recovery. As a result, for example, it is possible to eliminate an uninterruptible power system (UPS) for electricity failures and maintain a magnetic field for a long time.

In the example illustrated in FIG. 3, the superconducting magnet apparatus 200 includes the pre cooling pipe 209; however, the configuration of the superconducting magnet apparatus 200 according to the first embodiment is not limited to this, and the superconducting magnet apparatus 200 need not include the pre cooling pipe 209 and the cover 218.

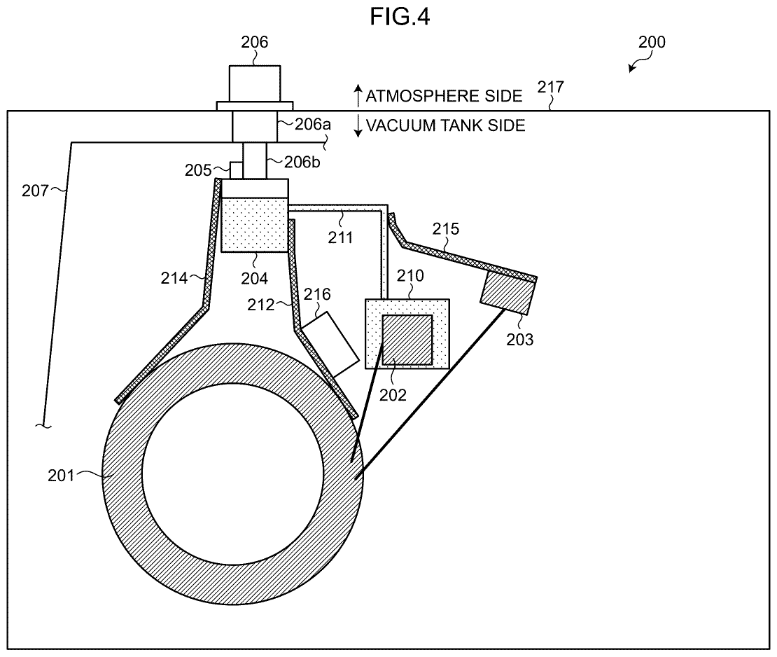

FIG. 4 is a diagram illustrating a modification of the superconducting magnet apparatus 200 according to the first embodiment.

For example, as illustrated in FIG. 4, the superconducting magnet apparatus 200 may exclude the pre cooling pipe 209, the cover 218, the solid heat conductor 213, and the thermal anchor 208 from the configuration illustrated in FIG. 3.

In the configuration, one of the ends of the solid heat conductor 214 thermally makes contact with the refrigerant tank 204 and the other end thermally makes contact with one part of the outer circumferential part of the superconducting coil 201 and the solid heat conductor 214 directly transmits the temperature of the refrigerant in the refrigerant tank 204 to the superconducting coil 201, thereby cooling the superconducting coil 201 to the second temperature.

The first embodiment has been described above, and the configurations of the superconducting magnet apparatus and the MRI apparatus that are described above are also enabled in a way that the configurations are changed partly as appropriate. Thus, modifications of the superconducting magnet apparatus and the MRI apparatus according to the first embodiment will be described as other embodiments. Note that in the following embodiments, aspects different from the embodiments described previously will be described mainly and components that fulfill the same role are denoted with the same reference numeral and detailed description thereof will be omitted.

### Second Embodiment

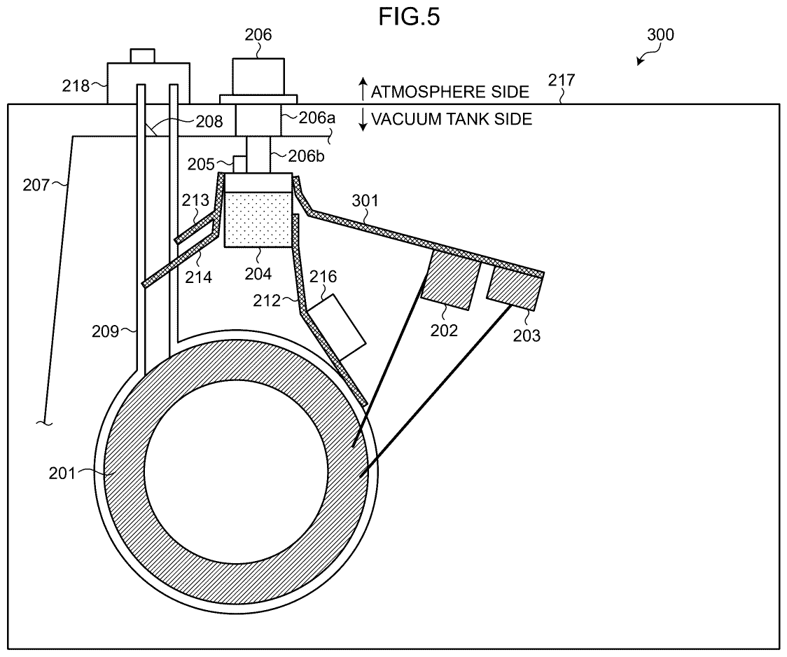

FIG. 5 is a diagram illustrating an example of a superconducting magnet apparatus 300 according to a second embodiment.

For example, as illustrated in FIG. 5, the superconducting magnet apparatus 300 according to the second embodiment is different from the superconducting magnet apparatus 200 according to the first embodiment in including a solid heat conductor 301 instead of the refrigerant tank 210 and the pipe 211.

Like the solid heat conductors 212 to 215, the solid heat conductor 301 is formed of metal (for example, pure aluminum or copper) having high heat conductivity and makes thermal connection between the refrigerant tank 204 and the structure 202 and the structure 203.

Specifically, one of the ends of the solid heat conductor 301 thermally makes contact with the refrigerant tank 204 and the other end thermally makes contact with each of the structure 202 and the structure 203 and the solid heat conductor 301 transmits the temperature of the refrigerant in the refrigerant tank 204 to the structure 202 and the structure 203, thereby cooling the structure 202 and the structure 203 to the second temperature.

In the solid heat conductor 301, at least two of parameters of size, heat conductivity, and heat load are set according to an operation temperature or superconductivity characteristics of each of the structure 202 and the structure 203.

According to the above-described configuration, the same effect as that of the first embodiment is achieved and, compared to the first embodiment, it is possible to cool the structure 202 without the refrigerant tank 210 and thus reduce manufacturing costs.

### Third Embodiment

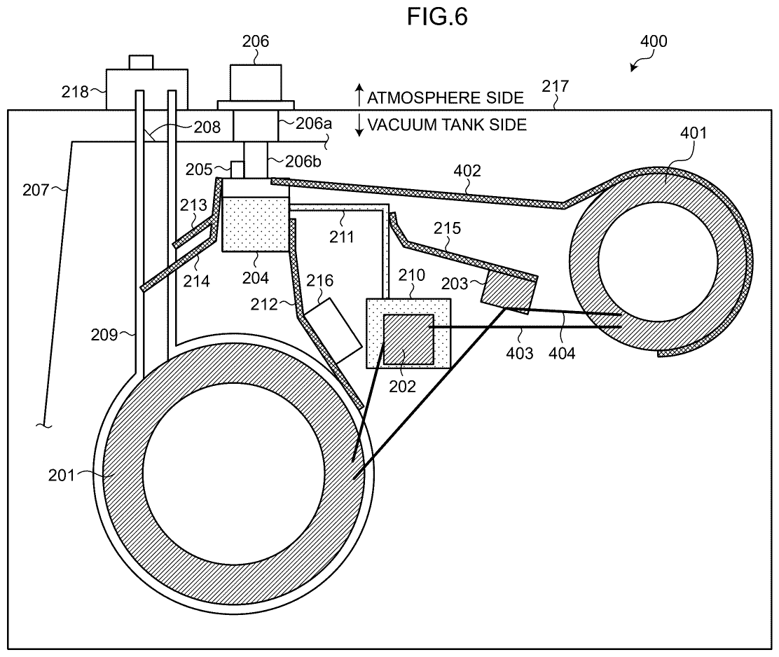

FIG. 6 is a diagram illustrating an example of a superconducting magnet apparatus 400 according to a third embodiment.

For example, as illustrated in FIG. 6, the superconducting magnet apparatus 400 according to the third embodiment is different from the superconducting magnet apparatus 200 according to the first embodiment in further including a superconducting coil 401, a solid heat conductor 402, a connector 403, and a connector 404.

The superconducting coil 401 is formed of a superconducting wire that forms a magnetic field. Specifically, the superconducting coil 401 is formed of a wire of a HTS material. The superconducting coil 401 is electrically connected to the structure 202 and the structure 203.

In other words, the superconducting magnet apparatus 400 according to the third embodiment has a hybrid cooling structure of a combination of the superconducting coil 201 of the LTS material and the superconducting coil 401 of the HTS material.

Like the solid heat conductors 212 to 215, the solid heat conductor 402 is formed of metal (for example, pure aluminum or copper) having high heat conductivity and makes thermal connection between the refrigerant tank 204 and the superconducting coil 401.

Specifically, one of the ends of the solid heat conductor 402 thermally makes contact with the refrigerant tank 204 and the other end thermally makes contact with an outer circumferential part of the superconducting coil 401 and the solid heat conductor 402 transmits the temperature of the refrigerant in the refrigerant tank 204 to the superconducting coil 401, thereby cooling the superconducting coil 401 to the second temperature.

In the solid heat conductor 402, at least two of parameters of size, heat conductivity, and heat load are set according to an operation temperature or superconductivity characteristics of the superconducting coil 401.

The connector 403 makes thermal connection between the superconducting coil 401 and the structure 202. The connector 404 makes thermal connection between the superconducting coil 401 and the structure 203. This makes it possible to uniformize the temperatures of the superconducting coil 201, the structure 202, the structure 203, and the superconducting coil 401 to the second temperature.

According to the above-described configuration, the same effect as that of the first embodiment is achieved and cooling the superconducting coil 201 and the superconducting coil 401 individually makes it possible to cool each of the superconducting coils efficiently in the hybrid cooling structure.

### Fourth Embodiment

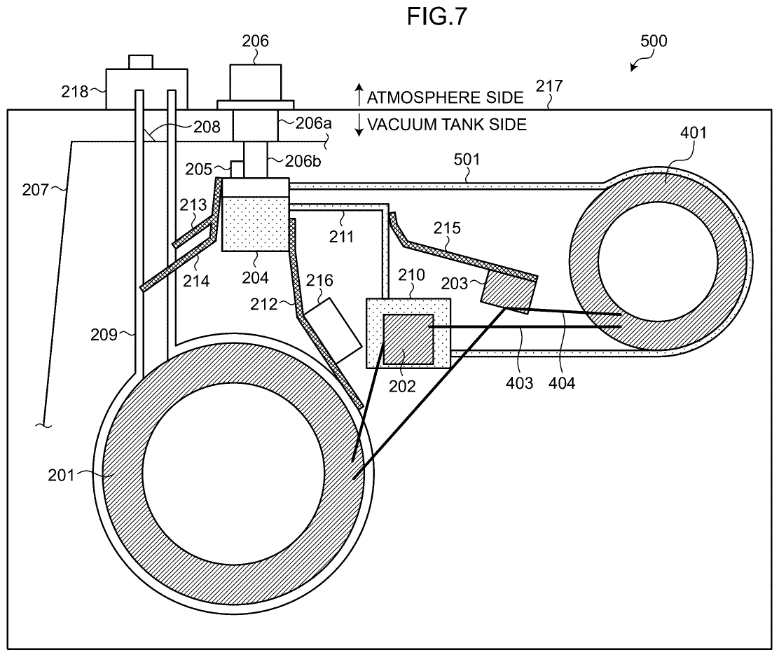

FIG. 7 is a diagram illustrating an example of a superconducting magnet apparatus 500 according to a fourth embodiment.

For example, as illustrated in FIG. 7, the superconducting magnet apparatus 500 according to the fourth embodiment is different from the superconducting magnet apparatus 400 according to the third embodiment in including a pipe 501 instead of the solid heat conductor 402.

The pipe 501 is arranged such that the pipe 501 thermally makes contact with the outer circumferential part of the superconducting coil 401 and the pipe 501 conveys the refrigerant from the refrigerant tank 204 to the refrigerant tank 210, thereby cooling the superconducting coil 401 to the second temperature.

In the pipe 501, at least two of parameters of size, heat conductivity, and heat load are set according to an operation temperature or superconductivity characteristics of the superconducting coil 401.

According to the above-described configuration, the same effect as that of the first embodiment is achieved and, compared to the superconducting magnet apparatus 400 according to the third embodiment, it is possible to cool the superconducting coil 401 using the pipe 501 through which the refrigerant passes and thus cool the superconducting coil 401 efficiently.

### Fifth Embodiment

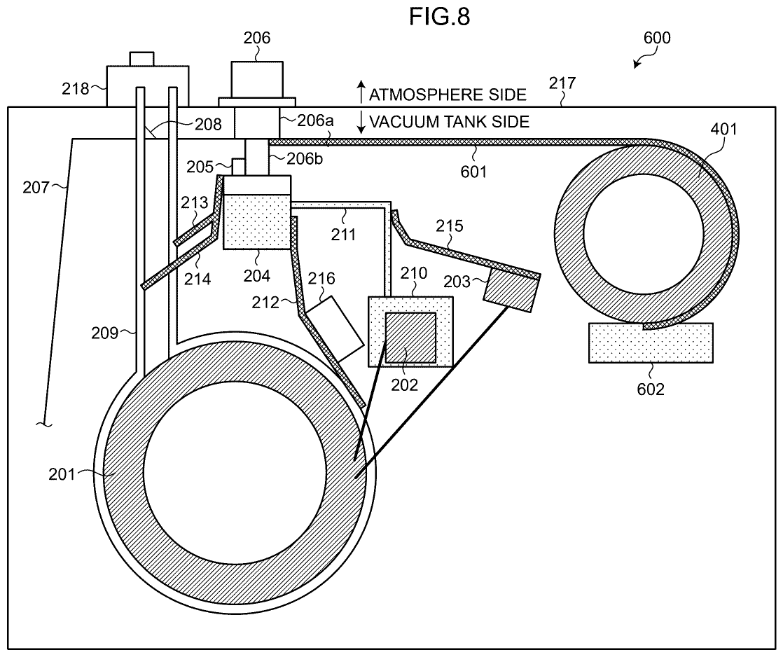

FIG. 8 is a diagram illustrating an example of a superconducting magnet apparatus 600 according to a fifth embodiment.

For example, as illustrated in FIG. 8, the superconducting magnet apparatus 600 according to the fifth embodiment is different from the superconducting magnet apparatus 400 according to the third embodiment in including a solid heat conductor 601 and a refrigerant tank 602 instead of the solid heat conductor 402 and the connectors 403 and 404.

Like the solid heat conductors 212 to 215, the solid heat conductor 601 is formed of metal (for example, pure aluminum or copper) having high heat conductivity and makes thermal connection between the high-temperature end 206a of the freezer 206 and the superconducting coil 401.

Specifically, one of the ends of the solid heat conductor 601 thermally makes contact with the high-temperature end 206a of the freezer 206 and the other end thermally makes contact with the outer circumferential part of the superconducting coil 401 and the solid heat conductor 601 transmits the temperature of the high-temperature end 206a of the freezer 206 to the superconducting coil 401, thereby cooling the superconducting coil 401 to the first temperature.

In the solid heat conductor 601, at least two of parameters of size, heat conductivity, and heat load are set according to an operation temperature or superconductivity characteristics of the superconducting coil 401.

The refrigerant tank 602 thermally makes contact with the superconducting coil 401 and cools the superconducting coil 401 in an auxiliary manner using a liquid or gas refrigerant with which the inside of the refrigerant tank 602 is filled.

According to the above-described configuration, the same effect as that of the first embodiment is achieved and, compared to the superconducting magnet apparatus 400 according to the third embodiment, it is possible to efficiently cool each of the superconducting coils in the hybrid cooling structure by cooling the superconducting coil 401 of the HTS material to the first temperature and cooling the superconducting coil 201 of the LTS material to the second temperature lower than the first temperature.

### Sixth Embodiment

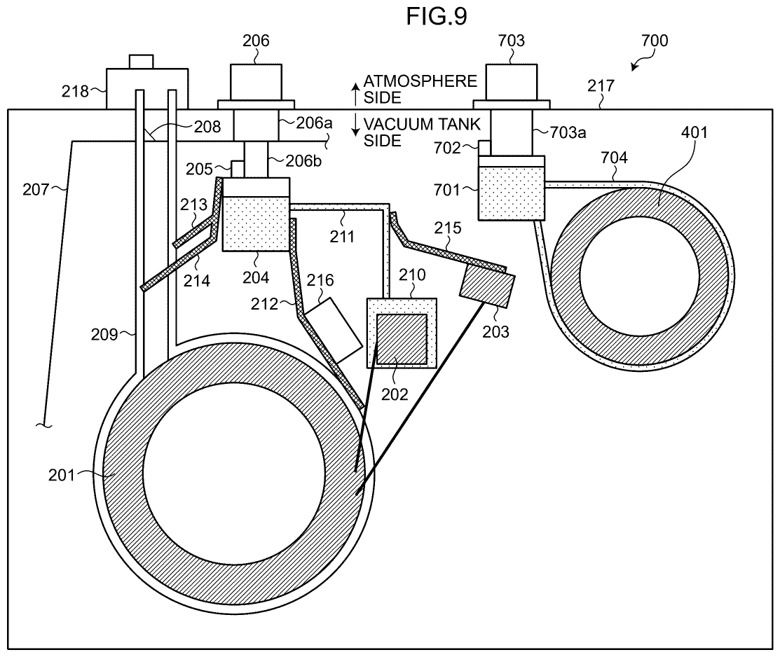

FIG. 9 is a diagram illustrating an example of a superconducting magnet apparatus 700 according to a sixth embodiment.

For example, as illustrated in FIG. 9, the superconducting magnet apparatus 700 according to the sixth embodiment is different from the superconducting magnet apparatus 600 according to the fifth embodiment in including a refrigerant tank 701, a heat exchanger 702, a freezer 703, and a pipe 704 instead of the solid heat conductor 601 and the refrigerant tank 602.

The refrigerant tank 701 stores a refrigerant, such as liquid nitrogen or liquid hydrogen.

The heat exchanger 702 is exposed to the inside of the refrigerant tank 701, liquefies the vaporized refrigerant again, and returns the liquefied refrigerant to the refrigerant tank 701.

The freezer 703 cools a refrigerant in the refrigerant tank 701. Specifically, the freezer 703 has a high-temperature end 703a at a first temperature (for example, 50K) and cools the refrigerant in the refrigerant tank 701 to the first temperature using the high-temperature end 703a.

Note that, like the freezer 206 described in the above-described embodiment, the freezer 703 may further has a low-temperature end at a second temperature (for example, 4K) lower than the first temperature.

The pipe 704 is arranged such that the pipe 704 thermally makes contact with the outer circumferential part of the superconducting coil 401 and cools the superconducting coil 401 to the first temperature by circulating the refrigerant in the refrigerant tank 701.

In the pipe 704, at least two of parameters of size, heat conductivity, and heat load are set according to an operation temperature or superconductivity characteristics of the superconducting coil 401.

In other words, the superconducting magnet apparatus 700 according to the sixth embodiment includes a plurality of freezers in which settings are made such that each of the freezers is able to maintain the superconducting state against a heat load caused by the structure to be cooled and the superconducting coil 401 formed of the wire of the HTS material is thermally connected to one of the freezers.

According to the above-described configuration, the same effects as those of the first and the fifth embodiments are achieved and, compared to the superconducting magnet apparatus 400 according to the third embodiment, it is possible to cool the superconducting coil 401 using the pipe 704 through which the refrigerant passes and thus cool the superconducting coil 401 more efficiently.

### Seventh Embodiment

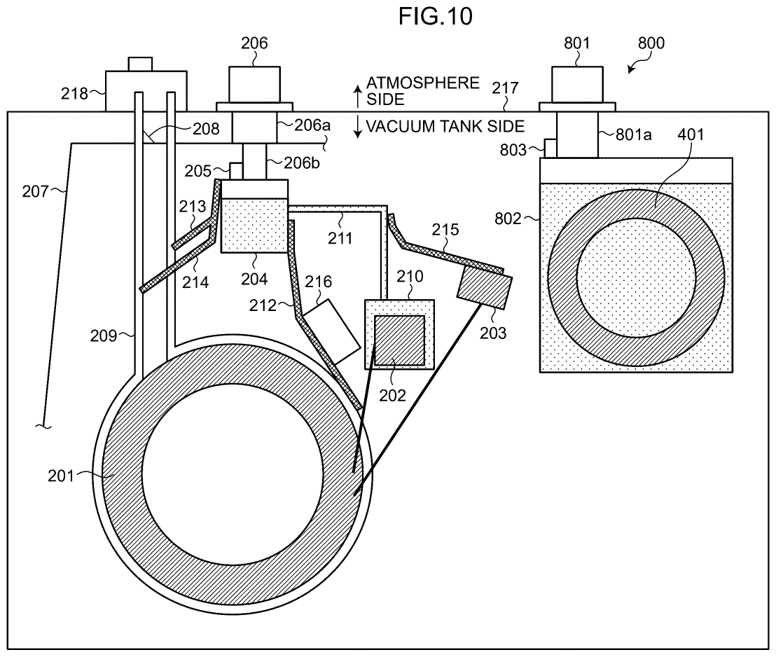

FIG. 10 is a diagram illustrating an example of a superconducting magnet apparatus 700 according to a seventh embodiment.

For example, as illustrated in FIG. 10, a superconducting magnet apparatus 800 according to the seventh embodiment is different from the superconducting magnet apparatus 600 according to the fifth embodiment in including a freezer 801, a refrigerant tank 802, and a heat exchanger 803 instead of the solid heat conductor 601 and the refrigerant tank 602.

The freezer 801 cools a refrigerant in the refrigerant tank 802. Specifically, the freezer 801 has a high-temperature end 801a at a first temperature (for example, 50K) and cools the refrigerant in the refrigerant tank 802 to the first temperature using the high-temperature end 801a. Note that, like the freezer 206 described in the above-described embodiment, the freezer 801 may further has a low-temperature end at a second temperature (for example, 4K) lower than the first temperature.

The refrigerant tank 802 stores the refrigerant, such as liquid nitrogen or liquid hydrogen, that is cooled by the freezer 801 and seals in the superconducting coil 401 in a state of being immersed in the refrigerant, thereby cooling the superconducting coil 401 to the first temperature.

The heat exchanger 803 is exposed to the inside of the refrigerant tank 802, liquefies the vaporized refrigerant again, and returns the liquefied refrigerant to the refrigerant tank 802.

In other words, as in the sixth embodiment, the superconducting magnet apparatus 800 according to the seventh embodiment includes a plurality of freezers in which settings are made such that each of the freezers is able to maintain the superconducting state against a heat load caused by the structure to be cooled and the superconducting coil 401 formed of the wire of the HTS material is thermally connected to one of the freezers.

According to the above-described configuration, the same effects as those of the first and the fifth embodiments are achieved and, compared to the superconducting magnet apparatus 700 according to the sixth embodiment, it is possible to directly cool the superconducting coil 401 using the refrigerant stored in the refrigerant tank 802 and thus cool the superconducting coil 401 more efficiently.

Also as for the superconducting magnet apparatuses 300 to 800 described in the second to seventh embodiments described above, as in the modification of the first embodiment illustrated in FIG. 4, the pre cooling pipe 209, the cover 218, the solid heat conductor 213, and the thermal anchor 208 may be excluded from the configurations illustrated in FIGS. 5 to 10.

### Eighth Embodiment

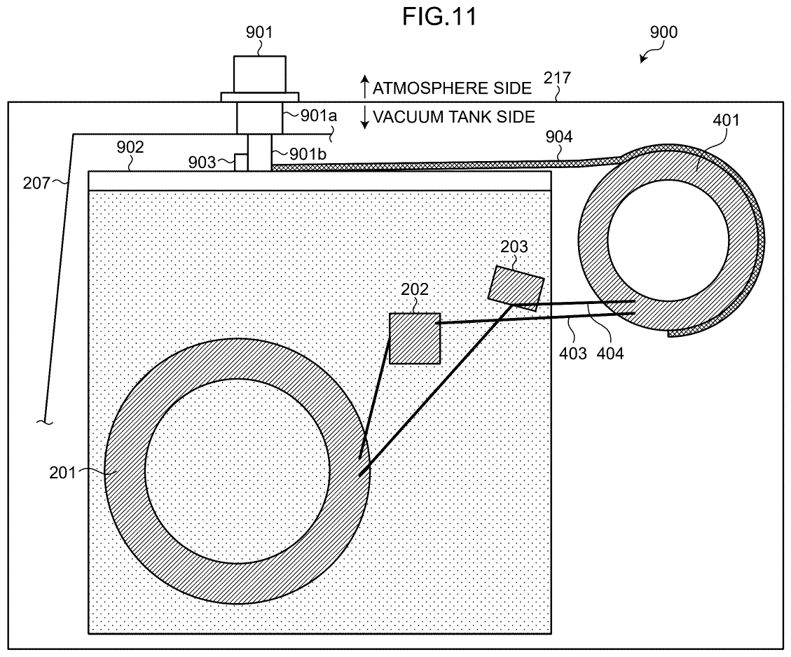

FIG. 11 is a diagram illustrating an example of a superconducting magnet apparatus 900 according to an eighth embodiment.

For example, as illustrated in FIG. 11, the superconducting magnet apparatus 900 according to the eighth embodiment is different from the superconducting magnet apparatus 400 according to the third embodiment in including a freezer 901, a refrigerant tank 902, a heat exchanger 903, and a solid heat conductor 904 instead of the refrigerant tank 204, the heat exchanger 205, the freezer 206, the thermal anchor 208, the pre cooling pipe 209, the refrigerant tank 210, the pipe 211, the solid heat conductors 212 to 215, the heat capacity ensuring member 216, the cover 218, and the solid heat conductor 402.

The freezer 901 cools a refrigerant in the refrigerant tank 902. Specifically, the freezer 901 has a high-temperature end 901a at a first temperature (for example, 50K) and a low-temperature end 901b at a second temperature (for example, 4K) lower than the first temperature and cools the refrigerant in the refrigerant tank 902 to the second temperature using the low-temperature end 901b.

The refrigerant tank 902 stores the refrigerant, such as liquid helium, that is cooled by the freezer 901 and seals in the superconducting coil 201, the structure 202, and the structure 203 in a state of being immersed in the refrigerant, thereby cooling the superconducting coil 201, the structure 202, and the structure 203 to the first temperature.

The heat exchanger 903 is exposed to the inside of the refrigerant tank 902, liquefies the vaporized refrigerant again, and returns the liquefied refrigerant to the refrigerant tank 902.

Like the solid heat conductor 402 described in the third embodiment, the solid heat conductor 904 is formed of metal (for example, pure aluminum or copper) having high heat conductivity and makes thermal connection between the refrigerant tank 902 and the superconducting coil 401.

Specifically, one of the ends of the solid heat conductor 904 thermally makes contact with the refrigerant tank 902 and the other end thermally makes contact with the outer circumferential part of the superconducting coil 401 and the solid heat conductor 904 transmits the temperature of the refrigerant in the refrigerant tank 902 to the superconducting coil 401, thereby cooling the superconducting coil 401 to the first temperature.

In the solid heat conductor 904, at least two of parameters of size, heat conductivity, and heat load are set according to an operation temperature or superconductivity characteristics of the superconducting coil 401.

According to the above-described configuration, the same effect as that of the first embodiment is achieved and, compared to the superconducting magnet apparatus 400 according to the third embodiment, it is possible to directly cool the superconducting coil 201, the structure 202, and the structure 203 using the refrigerant stored in the refrigerant tank 902 and thus cool the superconducting coil 201, the structure 202, and the structure 203 more efficiently.

### Other Embodiments

In the above-described embodiment, the example in which the heat capacity ensuring member 216 is attached to only the solid heat conductor 212 has been described; however, embodiments are not limited to this and, for example, a heat capacity ensuring member may be attached to all or part of another solid heat conductor similarly.

In the above-described embodiment, the parts where the solid heat conductors that make direct or indirect thermal connection between the pipe that conveys the refrigerant from the refrigerant tank to the structure to be cooled and the refrigerant tank and the structure to be cooled are arranged and the number of the solid heat conductors are not limited to the configuration illustrated in each of the embodiments and the site and the number of solid heat conductors may be changed appropriately according to the operation temperature or the superconductivity characteristics of the structure to be cooled. For example, a solid heat conductor may thermally make contact with a plurality of parts of the pipe. For example, the solid heat conductor may thermally make contact with a plurality of parts of the outer circumferential part of the superconducting coil. For example, the solid heat conductor may thermally make contact with one part or a plurality of parts of a side plate or an inner circumferential part of the superconducting coil.

In the above-described embodiment, a heater capable of adjusting the temperature may be arranged instead of any one of the solid heat conductor, the pipe, and the heat capacity ensuring member or in addition to the solid heat conductor, the pipe, and the heat capacity ensuring member. In that case, the heater may thermally make contact with the structure to be cooled and at least two of parameters of size, heat conductivity, and heat load may be set according to an operation temperature or superconductivity characteristics of the structure to be cooled.

In the description above, the example where the “processor” reads the program corresponding to each of the processing functions from the storge circuitry and executes the program has been described; however, embodiments are not limited to this. The word “processor” refers to, for example, circuitry of, a central processing unit (CPU), a graphics processing unit (GPU), an application specific integrated circuit (ASIC), a programmable logic device (for example, a simple programmable logic device (SPLD)), a complex programmable logic device (CPLD), or a field programmable gate array (FPGA). When the processor is, for example, a CPU, the processor reads a program that is saved in a storage and executes the program, thereby implementing each processing function. On the other hand, when the processor is an ASIC, instead of the program being saved in the storage, the processing function is directly incorporated in the circuitry of the processor as logic circuitry. Note that each of the processors of the embodiments is not limited to the case where each processor is configured as a single set of circuitry, and a plurality of sets of independent circuitry may be combined to configure a single processor to implement the processing functions. Furthermore, the components in FIG. 1 may be integrated into one processor to implement processing functions thereof.

The program that is executed by the processor is incorporated previously in a read only memory (ROM), a storage, and the like, and are provided. The program may be recorded in a file in a form installable in or executable by these devices in a computer readable recording medium, such as a CD (Compact Disk)-ROM, a FD (Flexible Disk), a CD-R (Recordable), or a DVD (Digital Versatile Disk) and may be provided. The program may be stored in a computer that is connected to a network, such as the Internet, and may be downloaded via the network and thus may be provided or distributed. For example, the program is configured in modules including each of the functional units described above. As for practical hardware, the CPU reads the program from a recording medium, such as a ROM, and executes the program and accordingly each of the modules is loaded in a main storage device and is generated in the main storage device.

In the above-described embodiments, each of the components of each of the apparatuses illustrated in the drawings is of functional ideas and need not necessarily be configured physically as illustrated in the drawings. In other words, specific modes of distribution or integration of each apparatus are not limited to those illustrated in the drawings and all or part of the apparatuses can be configured by being distributed or integrated functionally or physically in any unit according to various types of load, usage, etc. Furthermore, all or any part of each processing function that is implemented in each apparatus can be implemented by the CPU and using a program that is analyzed and executed by the CPU or can be implemented as hardware using a wired logic.

Among the processes described in the above-described embodiments, all or part of the process that is described as one performed automatically can be performed manually or all or part of the process that is described as one performed manually can be performed automatically by a known method. In addition to this, the process procedure, the control procedure, the specific names, and the information including various types of data and parameters that are presented in the description above and the drawings are changeable freely unless otherwise noted.

According to at least one of the embodiments described above, it is possible to efficiently cool a plurality of structures to be cooled while reducing the amount of the refrigerant.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

As for the embodiments above, the following note is disclosed as an aspect and selective features of the disclosure.

### Supplementary Note 1

A superconducting magnet apparatus comprising:
a superconducting coil that is formed of a superconducting wire that forms a magnetic field;
a structure that is formed of a superconductor and that is electrically connected to the superconducting coil;
a refrigerant tank that stores a refrigerant and that seals in the structure in a state of being immersed in the refrigerant;
a heat exchanger that is exposed to the inside of the refrigerant tank;
a freezer that cools the refrigerant;
a solid heat conductor that makes direct or indirect thermal connection between the refrigerant tank and the superconducting coil; and
a vacuum container that seals in the superconducting coil, the structure, the refrigerant tank, the heat exchanger, the freezer, and the solid heat conductor,
wherein the superconducting coil or the structure is formed using at least two structures having different operation temperatures or superconducting characteristics for superconduction.

What is claimed is:

1. A superconducting magnet apparatus comprising:
a superconducting coil that is formed of a superconducting wire that forms a magnetic field;
a structure that is formed of a superconductor and that is electrically connected to the superconducting coil;
a refrigerant tank that stores a refrigerant;
a heat exchanger that is exposed to inside of the refrigerant tank;
a freezer that cools the refrigerant;
a solid heat conductor that makes direct or indirect thermal connection between the refrigerant tank and the superconducting coil and the structure; and
a vacuum container that seals in the superconducting coil, the structure, the refrigerant tank, the heat exchanger, the freezer, and the solid heat conductor,
wherein the superconducting coil or the structure is formed using at least two structures having different operation temperatures or superconducting characteristics for superconduction.

2. The superconducting magnet apparatus according to claim 1, wherein the superconducting characteristic is a critical temperature, a critical magnetic field, or a critical current.

3. The superconducting magnet apparatus according to claim 1, wherein the superconducting coil or the structure is formed using at least two of a low-temperature superconducting material, a high-temperature superconducting material, a protective material, a matrix, and a base material having different properties of thermal conductivity or specific heat.

4. The superconducting magnet apparatus according to claim 1, wherein the solid heat conductor is formed of metal that is formed into a plate shape, an angular shape, a tape shape, or a sheet shape and that has high heat conductivity or metal that is formed into a form of a cylindrical pipe and in which heat conductivity is set according to a structure that makes thermal contact.

5. The superconducting magnet apparatus according to claim 1, further comprising:
a pipe that conveys the refrigerant from the refrigerant tank to at least any one of the structure and the superconducting coil; and
a heat capacity ensuring member that is attached to the solid heat conductor and that ensures heat capacity of the solid heat conductor.

6. The superconducting magnet apparatus according to claim 5, wherein at least one of members that are the solid heat conductor, the pipe, the heat capacity ensuring member, and a heater thermally makes contact with at least one part of a structure having small heat capacity out of the superconducting coil and the structure and at least two of parameters of size, heat conductivity, and heat load of the at least one of the members are set according to the operation temperature and the superconducting characteristics.

7. The superconducting magnet apparatus according to claim 5, wherein the solid heat conductor thermally makes contact with at least one part of the pipe.

8. The superconducting magnet apparatus according to claim 1, wherein the solid heat conductor thermally makes contact with at least one part of the superconducting coil.

9. The superconducting magnet apparatus according to claim 5, wherein the superconducting coil or the structure contains a high-temperature superconducting material or a low-temperature superconducting material,
wherein the superconducting coil or the structure is thermally connected to any one of a low-temperature end and a high-temperature end of the freezer via at least one of the refrigerant tank, the pipe, the solid heat conductor, and the refrigerant.

10. The superconducting magnet apparatus according to claim 5, wherein the superconducting coil or the structure includes a first superconducting coil or a second structure containing a low-temperature superconducting material, and a second superconducting coil or a second structure containing a high-temperature superconducting material,
wherein the first superconducting coil or the first structure is thermally connected to a low-temperature end of the freezer via at least one of the refrigerant tank, the pipe, the solid heat conductor, and the refrigerant,
wherein the second superconducting coil or the second structure is thermally connected to a high-temperature end of the freezer via at least one of the refrigerant tank, the pipe, the solid heat conductor, and the refrigerant.

11. The superconducting magnet apparatus according to claim 9, wherein the freezer includes one or more freezers in each of which a setting is made such that it is possible to maintain a superconducting state against a heat load caused by a structure to be cooled,
wherein the superconducting coil is thermally connected to the one or more freezers.

12. A magnetic resonance imaging apparatus comprising the superconducting magnet apparatus according to claim 1 as a static magnetic field magnet that generates a static magnetic field in an imaging space in which a subject is placed.
